(19) United States
(12) Patent Application Publication
(10) Pub. No.: US 2014/0069486 A1
(43) Pub. Date: Mar. 13, 2014

(54) Multi-Layer Photovoltaic Device

(71) Applicant: Scuint Corporation, Austin, TX (US)

(72) Inventor: Steven B. Snidow, Austin, TX (US)

(73) Assignee: Scuint Corporation, Austin, TX (US)

(21) Appl. No.: 14/025,824

(22) Filed: Sep. 12, 2013

Related U.S. Application Data
(60) Provisional application No. 61/700,779, filed on Sep. 13, 2012.

(51) Int. Cl. H01L 31/042; H01L 31/05

(52) U.S. Cl. CPC H01L 31/0422; H01L 31/0504
USPC 136/251

(57) ABSTRACT

A three dimensional solar photovoltaic device comprised of multiple rows of photovoltaic cells or smaller photovoltaic devices and that are situated in rows along a horizontal plane and that multiple rows of such photovoltaic cells, or small photovoltaic devices, are spaced vertically and that may be set into a rigid, and load-bearing capable shell, to effective a solar device that is stackable and may be integrated to other such photovoltaic devices.

### CROSS-REFERENCE TO RELATED APPLICATIONS

This application claims the benefits of the filing of U.S. Provisional Patent Application Ser. No. 61/700,779 entitled, Multi-Layer Photovoltaic Device, filed Sep. 13, 2012 and the specification thereof is incorporated herein by reference.

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISK APPENDIX

Not Applicable.

### TECHNICAL FIELD

The present invention is in the technical field of photovoltaic devices. More particularly, the present invention is in the technical field of photovoltaic panels and similar energy producing devices.

### BACKGROUND OF THE INVENTION

Conventional photovoltaic solar panels are made for the purpose of electricity generation from solar gain and the photovoltaic effect with the conventional design of photovoltaic panels to be, typically, comprised of a backing plate, an array of interconnected photovoltaic cells connected in series and/or parallel, electrical components, a flat and transparent glass cover that, together, are held within a solid weatherproof frame. Each panel's photovoltaic cell array will consist of a number of photovoltaic cells that are laid flat to form a plane and that are held between the backing plate and the glass cover. Tension is often achieved through use of the frame holding all the elements together and in place or the components may be laminated together. For use, each individual photovoltaic panel is oriented on a fixed, or adjustable, mounting system for the purpose of maximizing, for a particular site, its solar gain and, therefore, its electricity generation potential.

Depending on exact end user requirements, the photovoltaic panel is normally connected to other photovoltaic panels to form a photovoltaic panel array. The photovoltaic panel array is then typically connected to the end user's electrical system (e.g., a home) through an inverter and may also be connected to energy storage devices such as deep cycle batteries. Some photovoltaic panels may be used only to power single devices such as a gate opener. Placement of the photovoltaic panel, or array, is critical to solar gain and results in the placement of arrays away from skyline objects that may interfere with solar gain such as trees and buildings. This necessity often results in the placement of photovoltaic panels, or array, in open areas, such as a plain or a desert, or on rooftops. Further, and pending exact power requirements, the count of photovoltaic panels may vary and often necessitating an ad hoc arrangement of panels onto a rooftop diminishing aesthetic value of the property involved or otherwise not optimizing available space due to an imprecise fit between rooftop, or other space available, and photovoltaic panel sizes and that may therefore negatively impact desired performance characteristics of the panels.

In attempting to maximize the solar gain of the typical, two-dimensional, photovoltaic panel, or device, any structural, or load-bearing, attribute embodied in any photovoltaic panel, or device, is lost due to the typical design of a flat plane and leaving photovoltaic panels, or devices, to be typically set onto structures or otherwise applied to structural elements.

In each typical photovoltaic panel configuration and application, including photovoltaic panel arrays, the dimensions of the photovoltaic panel, or device, may be commonly expressed in two primary dimensions. For example, a common size panel is approximately three feet wide by five feet long, expressed as the X-axis and Y-axis, but will be often only about one inch thick (expressed as the Z-axis (i.e., vertical axis)). The typical photovoltaic device is designed to maximize the surface space, the space available for direct sunlight, as defined by the X-axis and Y-axis coordinates. Such design can be seen readily in the marketplace today and typically limiting the use of the Z-axis to only the thickness of a panel. However, limited use of the Z-axis for additional photovoltaic action has been achieved and is reflected in the below examples of prior art that also include prior art containing use of photovoltaic devices, or related devices, as a structural element.

U.S. Pat. No. 4,023,368 (Donald A. Kelly; May 17, 1977) teach us of a high density-third dimension geometry photovoltaic panel design. In this design, the inventor has used single-sided photovoltaic cells placed at an angle to the sun, or light source, to provide for additional photovoltaic cells for a defined space (i.e., per square foot). In one instance, the inventor has derived a wide “U” shape with wide, flat, bottom and whose vertical arms are slightly tilted and represent photovoltaic cells. To help assure adequate light gain to the vertical arms, a curved reflector is positioned between the photovoltaic cells such that light falling between two, facing, cells is split and reflected onto each individual cell. Similarly, inventor has an alternative approach that replaces the center positioned reflector with additional cells and roughly forming a “W” cross-section. This invention has utility and utilizes space more effectively than flat, traditional, panel designs but is also limited to one row of single-sided photovoltaic cells.

U.S. Pat. No. 5,994,641 (Michael J. Kardauskas; Nov. 30, 1999) teaches us of a solar module having a reflector between cells. The design offered though this patent is inherently similar to those of a traditional panel in the way that this design is also predominantly a two-dimensional (X-axis and Y-axis) design. However, the Kardauskas invention does use the Z-axis to a limited extent and also demonstrates the utility of spacing individual photovoltaic (solar) cells apart from each other. In this design, the inventor provides, in summary, for space between each flat photovoltaic cell and wherein such space has a reflective material applied to a grooved, three-dimensional, material that acts to provide incident light to be reflected from this surface to the top, transparent, substrate, such as glass, that will reflect or refract a portion of the reflected light back onto the adjoining photovoltaic cell(s) and providing for additional energy production.

U.S. Pat. No. 5,538,563 (Anthony W. Finkl; Jul. 23, 1996) teaches us of a solar energy concentrator apparatus for bifacial photovoltaic cells that is similar to Kelly above. Finkl shows two derivative designs in the invention. The first design is a “V” reflector wherein the “V” shape is elongated and also repeated to form, in essence, a corrugated substrate. At the bottom apex of each “V” a vertical (i.e., positioned at a 90-degree angle) bifacial photovoltaic cell is placed onto the substrate and such the light striking the 45-degree arms of the “V” reflector provide light to both sides of the bifacial photovoltaic cell. Finkl demonstrates a second design on which the bifacial photovoltaic cell is positioned flat (i.e., a zero degrees) and such that one side receives direct sunlight and the second, downward facing, side receives reflected light from one half of the “V” shaped substrate. Similar to Kelly, this patent has obvious utility and while using two sides of a cell for energy production still utilizes, like Kelly above, one row of cells for energy production.

U.S. Pat. No. 6,340,789 (Klaus Petritsch et al; Jan. 22, 2002) teaches us of a multilayer photovoltaic or photoconductive device design that utilizes multiple layers of semiconductor material to increase energy production. Unlike other photovoltaic inventions listed herein that rely on reflective material, or use of the Z-axis, or other approaches to help assure additional light strikes a photovoltaic cell, this invention increases the use of any light through additional layers of semiconductor (e.g., photovoltaic) material using, in essence, the Z-axis, at the most elemental point of the solar cell itself. The utility of such design is great. However, such utility is likely enhanced once combined with other approaches, such as those described herein, or concentrated light, to provide additional light to strike this improved photovoltaic surface.

U.S. Pat. No. 6,027,828 (Stan S. Hahn; Feb. 22, 2000) teaches us of a modular stackable battery pack and accessories in which each battery is formed such that each has two opposing faces that can be coupled with the opposite face of a similarly formed battery and such that the two, or more, batteries are connected, essentially, in a male-to-female, and stacked configuration. This invention has obvious utility for extending the useful life of any device that requires battery power.

U.S. Pat. No. 4,258,701 (Bruce S. Buckley; Mar. 31, 1981) teaches us of a solar collector panel comprised of a heat transmission module wherein a solar (thermal) collector, storage tank and other parts are fabricated as a unitary structure capable of bearing a load. This invention has obvious utility but the more unique attribute of it is that it is described as a solar thermal device capable of bearing a load. As described in the patent, an insulating layer contained within a frame may have applied to it more rigid surfaces, such as metal or fiberglass, affecting a composite sandwich of material that is less likely to buckle and thus becoming more load bearing.

### SUMMARY OF THE INVENTION

The present invention is a solar photovoltaic device, such as a panel, comprised of multiple rows of single-sided photovoltaic cells, two-sided photovoltaic cells and/or small single-sided, or two-sided, photovoltaic cell devices that may be electrically connected in series and, or, in parallel and such that the photovoltaic cells are effectively suspended in rows along a horizontal plane and that multiple rows of such photovoltaic cells are stacked vertically creating a three dimensional photovoltaic device that may be utilized alone or may also be placed into a rigid and load-bearing frame and whose sides may be transparent, solid, and, or, reflective and that, as a whole unit, may be further stacked onto similar such units to be physically, and electrically, interconnected to increase energy production and provide for the physical manifestation of structural components that may also be individually and, or, collectively, load-bearing.

The primary objective of the present invention is to provide for increased electricity generation, as compared to a traditional flat photovoltaic panel, from a fixed, two dimensional, space such as the ground surface or a roof top. Utilization of available space for electricity generation is particularly important for higher density, urban, areas.

The primary advantage of the present invention is to provide not only for the increased electricity generation from a given two dimensional space as compared to a traditional flat photovoltaic panel but also for the overall net increase of electricity through photovoltaic means by utilizing spaces that currently do not fit the current paradigm but that may be put to use utilizing a three dimensional photovoltaic device provided by the present invention.

Yet another advantage of the present invention is it is a photovoltaic device that can be load bearing and used for temporary or permanent construction of shelters, or other structures, providing not only the load bearing skeleton for the shelter but also the walls of a shelter or other constructed form.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWING

FIG. 1 is an isometric and exploded view of one component of the present invention;

FIG. 2 is an isometric and exploded view of an alternative manifestation of the component shown in FIG. 1;

FIG. 3 is an isometric and exploded view of a mounted photovoltaic cell configuration;

FIG. 4 is an isometric view of alternative components of the present invention;

FIG. 5 is an isometric view of the present invention with components shown in FIGS. 1-4;

FIG. 6 is an isometric view of an alternative manifestation of the present invention as shown in FIG. 5;

FIG. 7 is an isometric view of the combined elements of the present invention in application to form a structural unit;

FIG. 8A is an isometric views demonstrating alternative combinations of a single photovoltaic cell orientation and placement;

FIG. 8B are isometric views demonstrating alternative combinations of multiple photovoltaic cells orientation and placement;

FIG. 9 is an isometric view of an alternative embodiment to the present invention with structural frame.

### DETAILED DESCRIPTION OF THE INVENTION

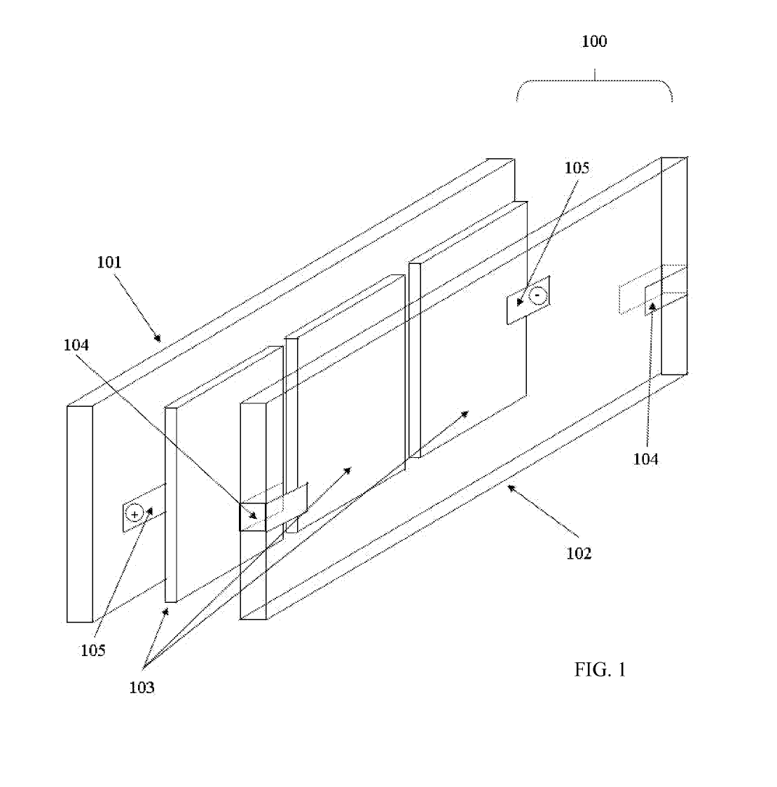

Referring in more detail to the invention in FIG. 1 there is a photovoltaic device 100 that is comprised of a non-conductive substrate 101, a transparent substrate 102 that provides light transmission to photovoltaic cells 103. Photovoltaic cells 103 may be wired in series or in parallel and that may have electrical leads 105. Electric leads 105 may connect to external electric leads 104 that are shown as clamped to transparent substrate 102 but may be understood to be to be affixed to either substrate 101 or 102. It should further be understood that FIG. 1 is an exploded view of this photovoltaic device and that the device is meant to be secured together by adhesives, or other means, and to affect a thin profile device with electrical leads 104 to be secured into a larger photovoltaic device such as a photovoltaic panel that may then contain a plurality of photovoltaic devices 100.

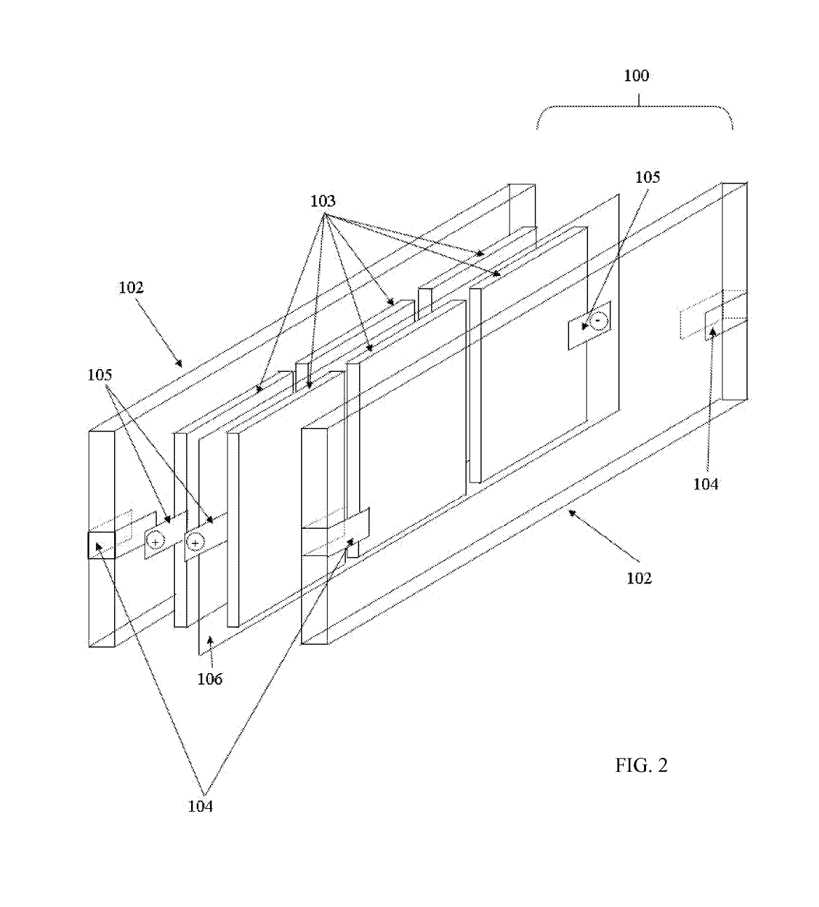

Now referring to FIG. 2, there is an alternative version of photovoltaic device 100 that is comprised of two sets of photovoltaic cells 103, that may each be wired in series or in parallel, and that may have electrical leads 105 and whose photo-active sides are set in opposing directions and that are separated by a nonconductive material 106. Photovoltaic cells 103 and nonconductive material 106 are held in place between two transparent substrates 102 that allow light to photovoltaic cells 103. Electric leads 105 may connect to external electric leads 104 that are shown as clamped to transparent substrates 102. It should further be understood that FIG. 2 is an exploded view of this photovoltaic device and that the device is meant to be secured together by adhesives, or other means, and to affect a thin profile device with electrical leads 104 to be secured into a larger photovoltaic device such as a photovoltaic panel that may then contain a plurality of photovoltaic devices 100. As shown, each side of photovoltaic device 100 is electrically separated from the other side and such that electrical leads 104 provide for the negative and positive electrical connections for each side of photovoltaic device 100 (i.e., a total of two negative and two positive connections for the whole device).

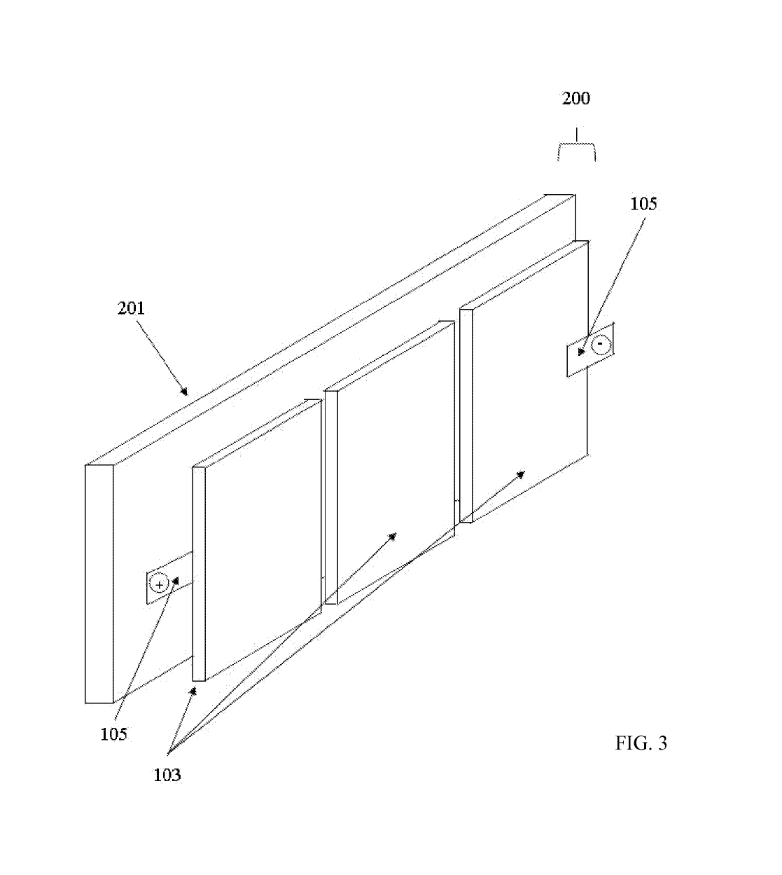

Now referring to FIG. 3, FIG. 3 is meant to demonstrate another approach of arranging photovoltaic cells onto a substrate to affect an approach similar to that shown in FIG. 1 and FIG. 2 and is further meant to show not only a single alternative approach but to describe only the generic form of multiple alternative approaches to the placement of photovoltaic cells in a configuration similar to that described in FIG. 1 and FIG. 2. The approach shown in FIG. 3 describes photovoltaic cell configuration 200 that is comprised of a non-conductive substrate 201 onto which photovoltaic cells 103 that are wired in series or in parallel and may be mounted and secured to substrate 201 by any means such as adhesives, clamps, encapsulation or other, and that have positive and negative electrical leads 105. It should be further understood that the photovoltaic cell configuration 200 as shown can be modified to include a second row of photovoltaic cells 103, wired in series or in parallel, mounted on the other flat side of substrate 201 and which may also be secured and electrically interconnected by the various means explained above. It should be further understood that while substrate 201 is shown as a monolithic substrate and comprised of one solid piece it may be configured in various shapes that affect the same result of holding the photovoltaic cells such as, by example, wherein substrate 201 may be considered an armature.

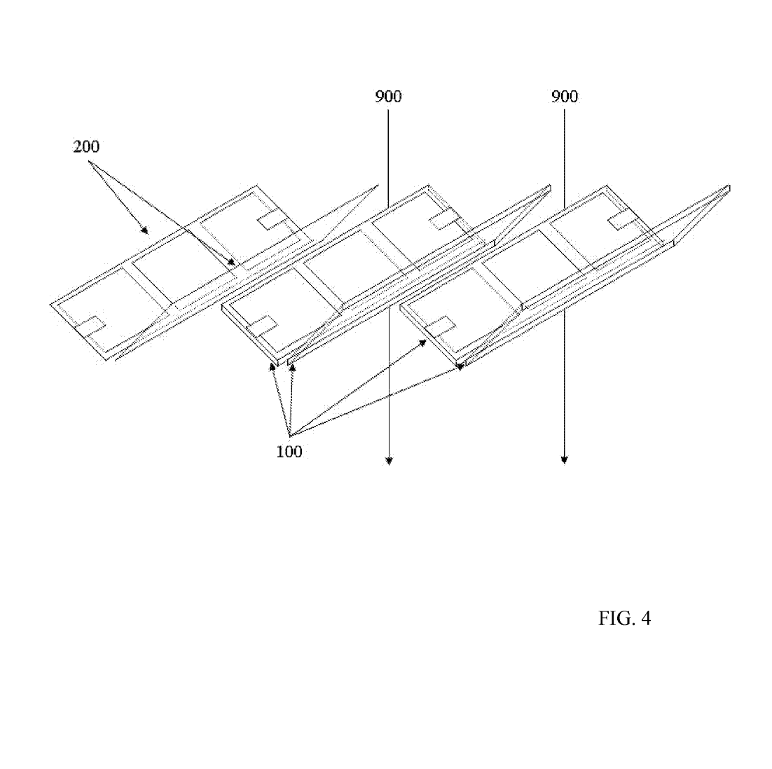

Referring now to FIG. 4, FIG. 4 is meant to show only the interior portion of a photovoltaic device, such as a photovoltaic panel, and that demonstrates a preferred embodiment and placement of photovoltaic device 100 paired with another photovoltaic device 100 to effect a “V” configuration as shown by the center “V” and the “V” configuration to the right of the figure. FIG. 4 also demonstrates a similar “V” configuration to the left and that should be understood to be comprised of two photovoltaic cell configurations 200. Photovoltaic cell configuration 200 is included to demonstrate that the three dimensional attributes of the present invention as explained in subsequent figures does not have to be achieved by photovoltaic device 100 but may be effected by similar approaches. Each “V” configuration, either type 100 or type 200, are shown in FIG. 4 as separated such that light 900 may be transmitted between the photovoltaic cell configurations 200 and/or photovoltaic devices 100 and that may allow incident, or reflected, light to additionally strike the bottom of small photovoltaic devices 100 and/or photovoltaic cell configurations 200.

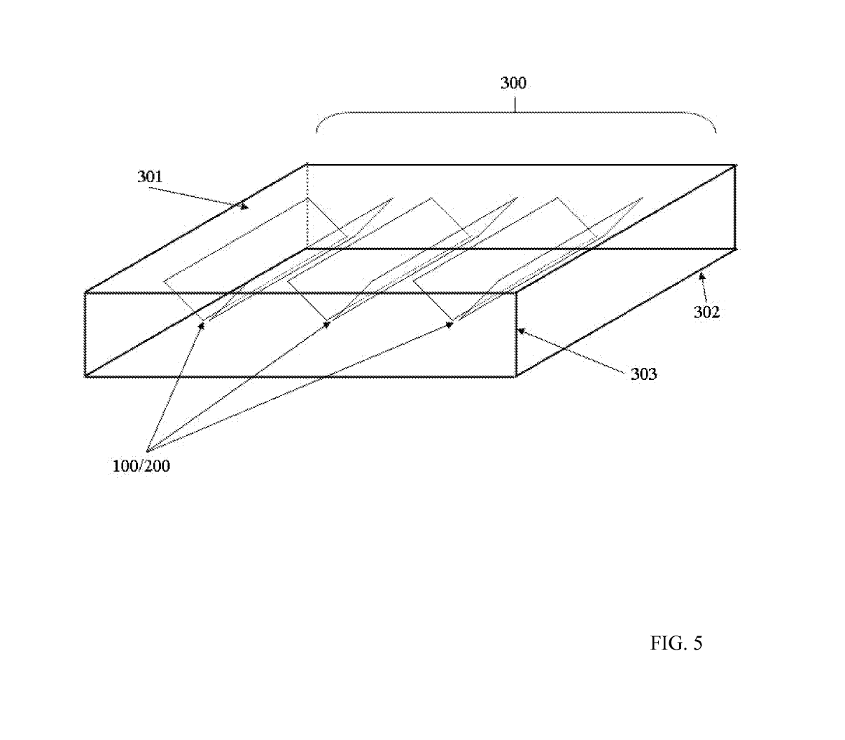

Now referring to FIG. 5, a larger photovoltaic device 300, such as a photovoltaic panel, is shown with top surface 301, bottom surface 302 and four sides 303. The interior of 300 is populated with smaller photovoltaic devices 100, photovoltaic cell configurations 200 or some combination of 100 and 200. As represented, smaller photovoltaic device 100 and photovoltaic cell configurations 200 are shown to be raised above bottom surface 302 which may, in application, be a reflective, transparent or non-reflective, non-transparent surface. Similarly, it should be understood that device sides 303 can be transparent, solid, reflective or some combination of transparent, solid and reflective and that the transparent portions may be made from glass, acrylic, plastic or other material. Not shown in FIG. 5 is the wiring and electrical interconnection of the plurality of smaller photovoltaic devices 100 and/or photovoltaic cell configurations 200 to each other and that should be understood to be wired together in series and/or in parallel and wired to external positive and negative lead connections and/or other electrical device(s), such as a junction box or microinverter, that service the whole photovoltaic device 300.

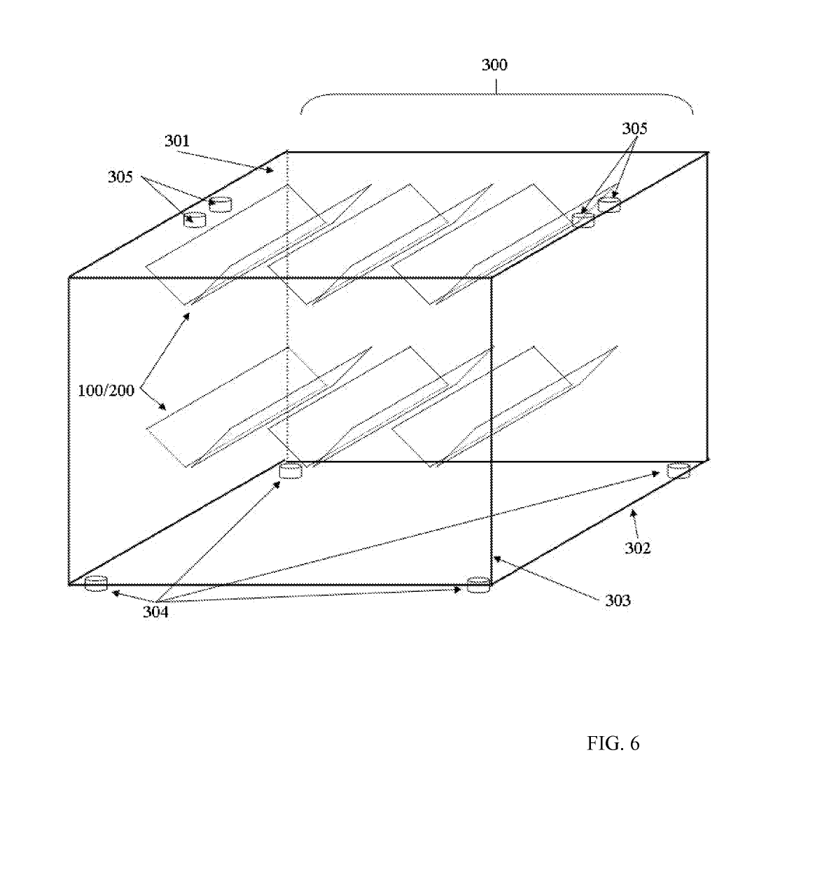

Referring now to FIG. 6, an alternative version of photovoltaic device 300, such as a photovoltaic panel, and that is taller than previously depicted, is shown with top surface 301, bottom surface 302 and four sides 303. The interior of 300 is populated with two rows of smaller photovoltaic devices 100, photovoltaic cell configurations 200, or some combination of 100 and 200. As represented, smaller photovoltaic devices 100 and photovoltaic cell configurations 200 are shown to be raised above bottom surface 302 which may, in application, be a reflective, transparent or non-reflective, non-transparent surface. Similarly, it should be understood that device sides 303 can be transparent, solid, reflective or some combination of transparent, solid and reflective and that the transparent portions may be made from glass, acrylic, plastic or other material. Not shown in FIG. 6 is the wiring and electrical interconnection of the plurality of smaller photovoltaic devices 100 and/or photovoltaic cell configurations 200 to each other and that should be understood to be wired together in series and/or in parallel and then wired to external positive and negative lead connections and/or other electrical device(s), such as a junction box or microinverter, that service the whole photovoltaic device 300. As depicted in FIG. 6, an alternative approach to such external lead connection are shown with male connection devices 304 and female connection devices 305 and that should be understood as connection devices that can effect a physical connection, an electrical connection or both. It should further be understood that the device can have additional rows (i.e., more than two rows) of smaller photovoltaic devices 100, photovoltaic cell configurations 200 or some combination of 100 and 200 and that would affect a taller height and increase the height-to-base ratio of the whole device with each successive row of smaller photovoltaic devices 100 and/or photovoltaic cell configurations 200.

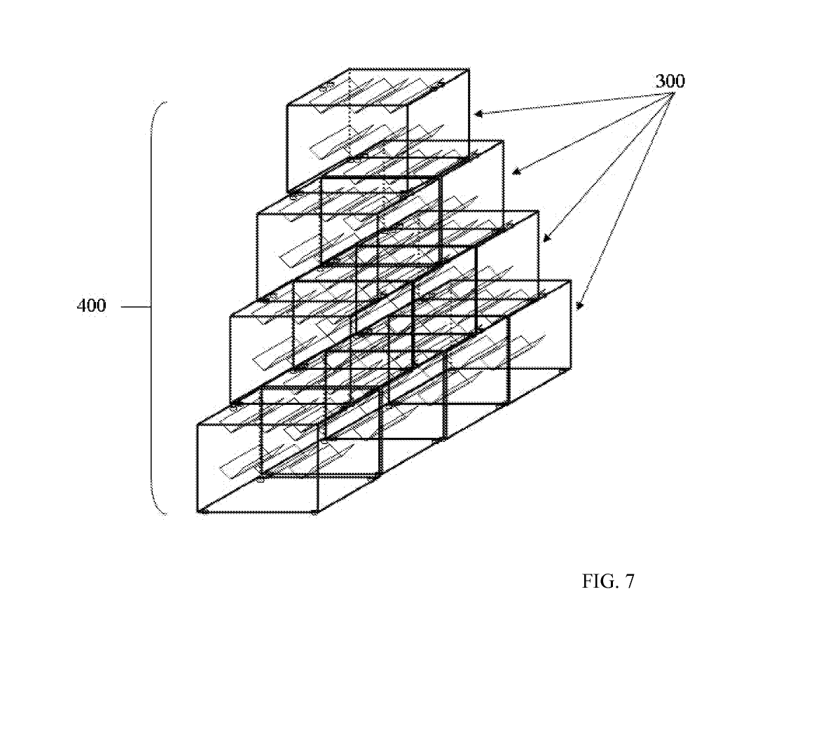

Referring now to FIG. 7, a photovoltaic array 400 is depicted as a portion of a standing wall comprised, for example, of ten three-dimensional photovoltaic devices 300, as shown in FIG. 6, that can be understood to be physically and electrically interconnected. As depicted, four photovoltaic devices 300 form the first row and the base for the second row of three photovoltaic devices 300 onto which a third row of two photovoltaic devices 300 are stacked followed by a fourth row comprised of a single photovoltaic device 300. It should be understood that this is only one depiction and that multiple and various means of stacking photovoltaic devices 300 are limited only by physical constraints and the load-bearing capacity of the photovoltaic devices 300. It should also be further understood that such photovoltaic array 400 may be used as a configurable structural unit that may provide adequate load-bearing strength for non-device items such as roofing or other materials and thus providing a dual-purpose such as a photovoltaic array and a shelter or a means of structural support.

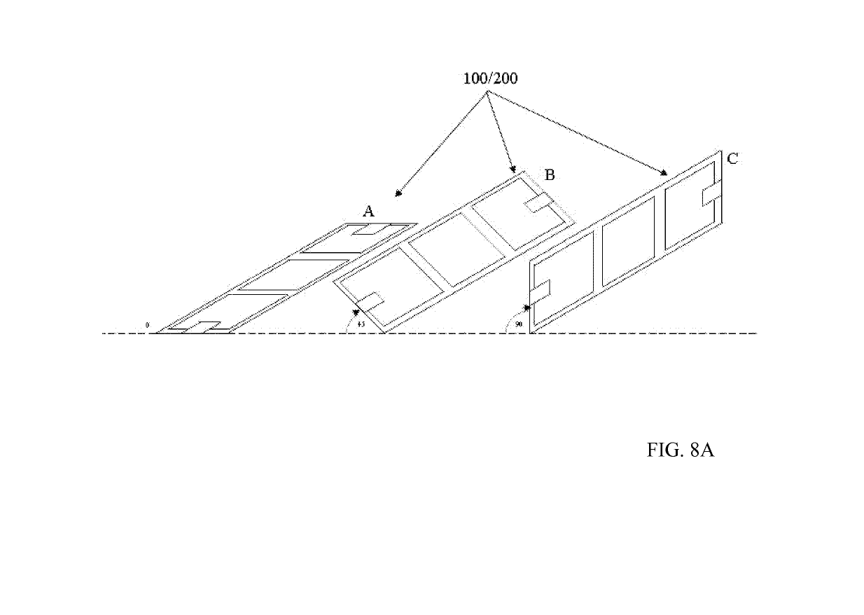

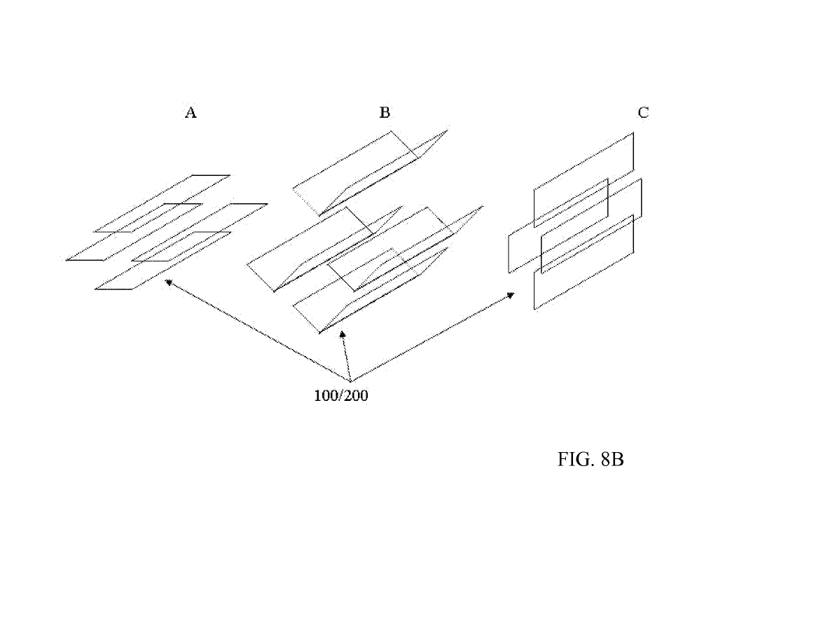

Now referring to FIG. 8A, FIG. 8A shows smaller photovoltaic device 100, or photovoltaic cell configuration 200, in three different orientations with Position A at 0-degrees (i.e., flat to the bottom substrate), Position B at 45-degrees and Position C at 90-degrees to the bottom substrate. While only three positions are demonstrated in FIG. 8A, it should be understood that any number of position and angles, or combinations of positions and angles, may be utilized.

Now referring to FIG. 8B and to further demonstrate the variability available in the three-dimensional space of photovoltaic device 300, FIG. 8B depicts a simplified three-row configuration of smaller photovoltaic devices 100, or photovoltaic cell configurations 200, and for each Position A-C and wherein Position B is shown with one preferred embodiment of smaller photovoltaic device 100 in the “V” configuration shown in prior figures.

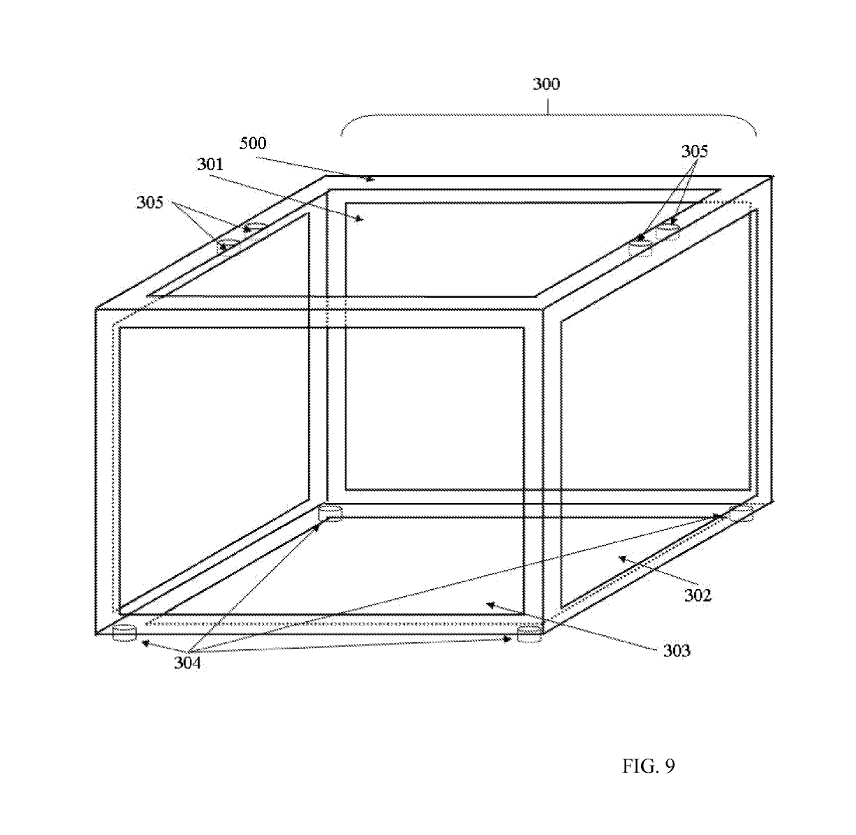

Referring now to FIG. 9, photovoltaic device 300 is shown in an alternative embodiment and to include frame 500 that is meant to aid in the structural and load-bearing potential of photovoltaic device 300 and should be understood to be comprised of sufficiently load-bearing material such as steel, aluminum, carbon fiber or other materials. Positioned against or otherwise held by frame structure 500 can be placed the top surface 301, bottom surface 302 and each of four sides 303 of photovoltaic device 300. As depicted in FIG. 9, male connection devices 304 and female connection devices 305 are contained within the frame structure 500 but it should be understood that male connection devices 304 and female connection devices 305 do not have to be located within frame structure 500. Further, FIG. 9 is simplified to demonstrate the frame concept and does not include smaller photovoltaic devices 100, or photovoltaic cell configurations 200, that should be understood to be a part of and contained within this framed device.

The advantages of the present invention include, without limitation, the ability to provide a three dimensional enclosure for the placement of a plurality of photovoltaic cells that can, in sum, provide for greater generation of electricity than a conventional, flat, photovoltaic panel, comprised of the same photovoltaic cell material within the same two dimensional area.

In broad embodiment, the present invention is a photovoltaic device comprised of four primary elements. The first element is the plurality of photovoltaic cells that may be suspended at various angles and that may include bifacial arrangements. The second element is the use of vertical space to arrange the plurality of photovoltaic cells and forming a three dimensional geometric shape that may become load bearing. The third element is to provide structural integrity to the device through engineering, such as a frame, in order to assure the device's load bearing capability and such that the device may be used as means of support including becoming a structural element of a shelter. The fourth element is to provide for male-to-female physical and electrical interconnections so the device may be stacked and where such interconnections can provide additional structural integrity and electrical connection.

### DESCRIPTION OF THE PREFERRED EMBODIMENTS (BEST MODES FOR CARRYING OUT THE INVENTION)

The present invention may be used as a photovoltaic panel, or device, capable of producing electricity through the photovoltaic effect and that may be configured as a small photovoltaic panel, or device, a larger photovoltaic panel, a vertically stacked photovoltaic device and/or used in different combinations to form a photovoltaic array.

As a preferred embodiment, the present invention is a load bearing photovoltaic device containing vertically stacked photovoltaic cells such that the device generates electricity in addition to its secondary role as a structural support. In its preferred embodiment, the present invention can be stacked onto other, similarly constructed, present invention units to construct a wall, column or other structural support while also providing for additional generation of electricity by capturing more light during early morning and late afternoon hours. In its preferred embodiment, the present invention also provides for mobility through the ability to move, stack and remove the present invention units from one area to another and over time.

The present invention may be utilized as a substitute to and improvement over traditional fixed photovoltaic panels whose designs are primarily two dimensional and flat and that are, thereby, limited in their individual capacity to generate electricity either, typically, being fixed and gaining light through only a portion of the day or being attached to a tracking device to gain more light through the day. The present invention, as a stationary, but vertical, design provides for electricity generation through the day by capturing the sun's light earlier and later and also through the day via the spaced position of the various rows of interior photovoltaic cells.

### INDUSTRIAL APPLICABILITY

The invention is further illustrated by the following non-limiting examples.

### Example 1

The present invention may act as a small and standalone photovoltaic device that may be used in a remote area to recharge a battery that powers a gate opener. For example, the present invention may be comprised of several photovoltaic cells mounted onto long substrates and where a plurality of those substrates are effectively suspended at an angle and in multiple vertical rows within the device. The suspended photovoltaic cells, and substrates, are physically connected to the sides of the device or to an armature and by such physical connection also electrically interconnected to a common negative and a common positive lead. All components are, in this example, situated within a ten inch square base clear container that is twenty inches tall and providing for several rows of photovoltaic cells and substrates to be spaced vertically between each other. The whole device is then mounted on top of the wooden post near to the gate charging unit and is electrically connected to the recharging battery. In this example, the present invention utilizes vertical space to place the photovoltaic cells instead of fixing the photovoltaic cells onto a two dimensional plane as found in typical photovoltaic panel designs. Further, because the photovoltaic cells are arranged in rows and vertically stacked to gain sunlight for the generation of electricity, the present invention can be mounted to the top of the pole instead of the side of the pole, as with typical photovoltaic panel designs, and may, therefore, have greater electricity generation through its elevated position and access to the sun's rays throughout the day.

### Example 2

The present invention may act as a larger photovoltaic device meant to power an average sized residence. In 2011, the average American home used 940 kilowatt hours per month or, on average, 2.57 kilowatt hours per day. To create this amount of electricity using the present invention, the present invention can be placed on the roof of a house in a 25 square foot configuration that is comprised of a square footprint of five feet by five feet and further comprised of a vertical footprint of eight, or less, inches. The present invention would be comprised of transparent sides and top constructed from a clear, and UV stable, material such as acrylic. The present invention would be further comprised of two vertical rows of photovoltaic cells mounted on substrates and where the cells and substrates are arranged in long rows and tiled at alternating 45-degree angles. The rows of cells and substrate are spaced apart from each other within each row and vertically to allow sunlight. By comparison, the same electricity generation from a typical three foot by five foot photovoltaic panel will require three panels and a 45 square foot print. The present invention is connected to the residence's electrical system and/or deep cycle storage battery.

### Example 3

The present invention may act as a portable and stackable photovoltaic device. For example, the present invention is comprised of a plurality of photovoltaic cells situated onto long, thin, substrates and where such cells and substrates are physically and electrically connected to the interior of a rigid, clear, case whose dimensions are twelve inches long by six inches wide and six inches tall. The present invention is reinforced with a metal cage on its edges and that bear positive and negative lead connections.

With this version of the present invention a military force may take a number of units of the present invention into the field where the need to power the soldier's various devices is critical. The soldiers may take the number of units and stack them to form a “V” shaped wall with one corner and two straight sections. The exterior portion of the “V” may be oriented to the sun for greater solar gain. When built to sufficient height, a tarp may be affixed to the top of the wall and draped over the interior portion of the “V” and thus providing temporary shelter. While in place, the present invention units can be used individually or to create optional power signatures with higher amounts of volts or amps by connecting the units in various configurations. This provides the soldiers options to power various small-to-large electrical devices. When the soldiers need to relocate their camp the present invention units can be disassembled from the wall configuration and relocated and re-set into an alternative configuration suitable for the new field conditions.

The preceding examples can be repeated with similar success by substituting the generically or specifically described parameters and/or operating conditions of this invention for those used in the preceding examples.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

I claim:

1. A photovoltaic device comprised of a rigid enclosure whose vertical walls and horizontal cover are transparent and that contains at least vertical two rows of single-sided photovoltaic cells mounted within the rigid structure that are mounted at an angle from 0-90 degrees as measured from the device base and where such photovoltaic cells are electrically interconnected in series, parallel or both and where the rows of photovoltaic cells are separated vertically by a minimum of one-half the shortest lateral dimension of the photovoltaic cells and where the overall photovoltaic device has positive and negative electrical interconnections to at least one other electrical device;

2. A photovoltaic device comprised of a rigid enclosure whose vertical walls and horizontal cover are transparent and whose interior horizontal base is reflective and that contains at least vertical two rows of two-sided photovoltaic cells mounted within the rigid structure that are mounted at an angle from 0-90 degrees as measured from the device base and where such photovoltaic cells are electrically interconnected in series, parallel or both and where the rows of photovoltaic cells are separated vertically by a minimum of one-half the shortest lateral dimension of the photovoltaic cells and where the overall photovoltaic device has positive and negative electrical interconnections to at least one other electrical device;

3. A photovoltaic device comprised of a rigid enclosure whose vertical walls and horizontal cover and base are transparent and that contains a plurality of photovoltaic cells and where the device's shell is sufficient to bear a load of a least one other such device and where the photovoltaic device has positive and negative electrical interconnections to at least one other electrical device;

4. A photovoltaic device comprised of a rigid enclosure whose vertical walls and horizontal cover and base are transparent and that contains a plurality of photovoltaic cells and that is reinforced with another rigid material to provide sufficient strength to bear a load of a least one other such device and where the photovoltaic device has positive and negative electrical interconnections to at least one other electrical device.
